(19) United States
(12) Patent Application Publication
(10) Pub. No.: US 2013/0115369 A1
(43) Pub. Date: May 9, 2013

(54) APPARATUS FOR FORMING CIRCUIT PATTERN ON PCB AND METHOD FOR FORMING CIRCUIT PATTERN USING THE SAME

(71) Applicants: Shang Hoon Seo, Seoul (KR); Seung Hwan Kim, Gyeonggi-do (KR); Suk Jin Ham, Seoul (KR)

(72) Inventors: Shang Hoon Seo, Seoul (KR); Seung Hwan Kim, Gyeonggi-do (KR); Suk Jin Ham, Seoul (KR)

(73) Assignee: SAMSUNG ELECTRO-MECHANICS CO., LTD., Suwon (KR)

(21) Appl. No.: 13/482,452

(22) Filed: May 29, 2012

(30) Foreign Application Priority Data
Nov. 4, 2011 (KR) 10-2011-0114465

(51) Int. Cl. H05K 3/12

(52) U.S. Cl. 427/98.4; 118/704

(57) ABSTRACT

Disclosed herein is a method for forming a pattern on a printed circuit board (PCB), including: printing a metallic material on a board through a plurality of nozzles; and sintering the metallic material with extra power from power for driving the plurality of nozzles to form a circuit pattern, whereby the circuit pattern can be easily formed.

### CROSS REFERENCE(S) TO RELATED APPLICATIONS

This application claims the benefit under 35 U.S.C. Section 119 of Korean Patent Application Serial No. 10-2011-0114465, entitled “Apparatus for Forming Circuit Pattern on PCB and Method for Forming Circuit Pattern Using the Same” filed on Nov. 4, 2011, which is hereby incorporated by reference in its entirety into this application.

### BACKGROUND OF THE INVENTION

1. Technical Field

The present invention relates to an apparatus for forming a circuit pattern on a printed circuit board (PCB) and a method for forming a circuit pattern using the same, and more particularly, to an apparatus for forming a circuit pattern on a PCB capable of forming a circuit pattern by printing conductive ink on a board and a method for forming a circuit pattern using the same.

2. Description of the Related Art

Recently, as electronic devices and products become highly developed, electronic devices and products are reduced in size and technical integration has steadily advanced, and a fabrication process of a PCB used for electronic devices and products is required to variably change according to the reduction in size and technical integration.

The technology with respect to methods for fabricating a PCB has been developed from an initial one-sided PCB to a double-sided PCB and to a multilayered PCB, and in particular, a fabrication method, so-called a build-up method, has been recently employed to fabricate a multilayered PCB.

Meanwhile, as electronic devices tend to be lighter, thinner, shorter, and smaller, a circuit pattern formed on a PCB is becoming finer, and to this end, in the related art, a circuit pattern is formed according to lithography of an etching and plating method in which a required pattern region remains on a base board with copper coated on an entire surface thereof while unnecessary regions are removed, thus fabricating a PCB.

However, in the related art, when a PCB is fabricated by using the lithography method, exposing preprocessing, dry film coating, exposing, developing, and etching operations are performed to form a circuit of a single layer, the number of processes is so many that high fabrication costs are incurred in view of labor cost and facility maintenance.

Also, when the exposing, developing, and delaminating processes are repeatedly performed for the etching and plating method, a large amount of alkali solution is used in developing a dry film and a large amount of copper chloride solution is used for an etching operation, or the like, causing a great deal of environmental waste.

Thus, in the art, a method for solving the problems of the related art lithography method, implementing a fine circuit pattern, and solving the environmental problem is required.

### SUMMARY OF THE INVENTION

An object of the present invention is to provide an apparatus for forming a circuit pattern on a printed circuit board (PCB) and a method for forming a circuit pattern using the same capable of forming a circuit pattern by directly printing a metallic material on a board and easily sintering the metallic material by using resistant heat generated from the metallic material.

Another object of the present invention is to provide an apparatus for forming a circuit pattern on a printed circuit board (PCB) and a method for forming a circuit pattern using the same capable of directly printing a metallic material on a board through a plurality of nozzles and after driving the plurality of nozzles, applying the remaining extra power to the metallic material to easily sinter the metallic material to thus form a circuit pattern.

According to an exemplary embodiment of the present invention, there is provided a method for forming a pattern on a printed circuit board (PCB), including: printing a metallic material on a board through a plurality of nozzles; and sintering the metallic material with extra power from the power used for driving the plurality of nozzles to form a circuit pattern.

The forming of the circuit pattern may include: applying extra power remaining after driving the plurality of nozzles to the metallic material; and sintering the metallic material by using heat generated by the extra power to form a circuit pattern.

The extra power remaining after driving the plurality of nozzles may be remaining power excluding driving power used to drive the nozzles from power applied to drive the entirety of the plurality of nozzles.

The metallic material may be conductive ink containing metal particles.

In the printing of the metallic material on the board, the metallic material may be printed by selectively jetting the conductive ink from the plurality of nozzles.

The method may further include: generating a pulse control signal for driving the plurality of nozzles and outputting the generated pulse control signal, before the printing of the metallic material on the board.

The method may further include: generating a plurality of driving signals corresponding to the plurality of nozzles according to the pulse control signal.

The method may further include: applying power for driving all of the plurality of nozzles, before the printing of the metallic material on the board.

In the applying of the extra power from the power for driving the plurality of nozzles to the metallic material, the extra power may be applied to both ends of an electrode of the metallic material to generate resistant heat.

The board may be made of an organic material.

According to another exemplary embodiment of the present invention, there is provided an apparatus for forming a pattern on a printed circuit board (PCB), including: a controlling unit generating a pulse control signal for driving a plurality of nozzles and outputting the generated pulse control signal; and a driving unit providing control to selectively jet a metallic material to a board through the plurality of nozzles according to the pulse control signal and providing control to sinter the metallic material by using extra power from the power for driving the plurality of nozzles to form a circuit pattern.

The driving unit may control the application of the remaining extra power after driving the plurality of nozzles to the metallic material.

The metallic material may be sintered by resistant heat generated by the extra power to form the circuit pattern.

The driving unit may include a driving controller generating a plurality of driving signals corresponding to the plurality of nozzles according to the pulse control signal.

The driving unit may include an extra power controller controlling the application of the remaining extra power after driving the plurality of nozzles to the metallic material.

The apparatus may further include: a power source unit applying power for driving all of the plurality of nozzles to the driving unit.

The extra power from the power for driving the plurality of nozzles may be remaining power excluding driving power used to drive the nozzles from power applied to drive all of the plurality of nozzles.

### BRIEF DESCRIPTION OF THE DRAWINGS

FIG. 1 is a view showing a configuration of an apparatus for forming a circuit pattern on a printed circuit board (PCB) according to an exemplary embodiment of the present invention;

FIG. 2 is a flow chart illustrating a process of forming a circuit pattern on a PCB according to an exemplary embodiment of the present invention; and

FIGS. 3 through 6 are views showing a process of forming a circuit pattern on a PCB according to an exemplary embodiment of the present invention, wherein

FIG. 3 is a view showing a board;

FIG. 4 is a view showing printing of a metallic material by using a printer head;

FIG. 5 is a view showing application of power to both ends of the electrodes of the metallic material; and

FIG. 6 is a view showing formation of a circuit pattern.

### DESCRIPTION OF THE PREFERRED EXEMPLARY EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, embodiments of the present invention will be described in detail with reference to the accompanying drawings.

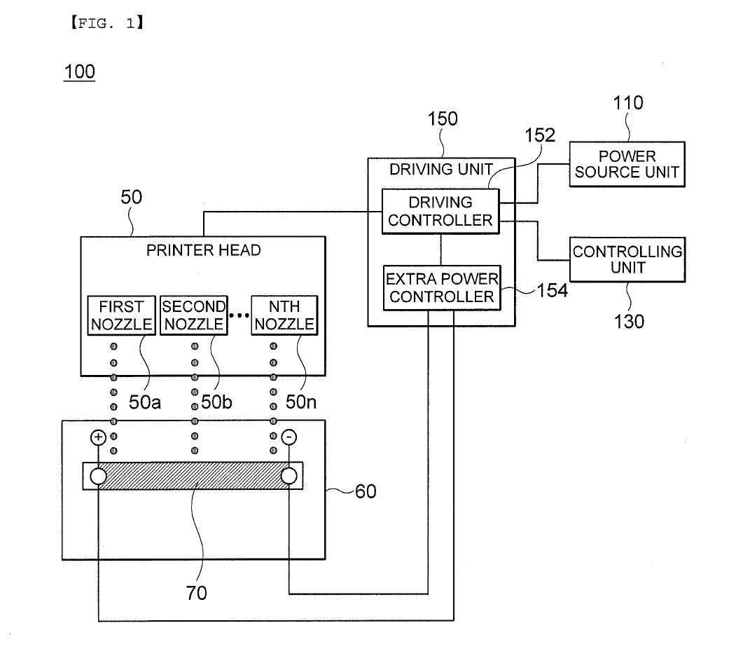

FIG. 1 is a view showing a configuration of an apparatus for forming a circuit pattern on a printed circuit board (PCB) according to an exemplary embodiment of the present invention;

As shown in FIG. 1, an apparatus 100 for forming a circuit pattern on a PCB may include a power source unit 110, a controlling unit 130, and a driving unit 150.

First, the apparatus 100 for forming a circuit pattern on a PCB forms a circuit pattern on a PCB by using an inkjet printer head. The inkjet printer head refers to a device jetting ink through a plurality of nozzles by using a piezoelectric element and upper and lower electrodes provided at upper and lower portions of the piezoelectric element.

Here, the piezoelectric element, a transducer obtained by sintering a piezoelectric material, generates electricity when mechanical force is applied thereto, or conversely, generates mechanical force when electricity is applied thereto. The piezoelectric material includes, for example, crystal, tourmaline, Rochelle salt, and the like, and recently developed artificial crystals such as barium titanate, monoammonium phosphate, ethylenediamine tartrate, and the like, may also be used as a piezoelectric material having excellent piezoelectricity.

When a driving signal is applied to the piezoelectric element through the upper and lower electrodes (i.e., when there is a potential difference between both electrodes), the piezoelectric element performs a deformation movement of expansion and contraction to serve as a type of pump pressing ink through the nozzles, which is then jetted out.

Hereinafter, the components of the apparatus 100 for forming a circuit pattern on a PCB will be described. The power source unit 110 generates power for driving all of a plurality of nozzles 50a to 50n, namely, a printer head 50. For example, the power source unit 110 may generate a predetermined voltage (e.g., 250V) and a predetermined current (e.g., 5 A) and apply the same to the driving unit 150.

When an external signal (e.g., a trigger signal) for driving the printer head 50 is applied from the outside, the controlling unit 130 may generate a pulse control signal for driving the plurality of nozzles and output the same.

Here, the pulse control signal is a pulse width modulation (PWM) signal available for adjustment of a duty ratio, and may include frequency information, rising/falling time, information regarding a selectively driven nozzle, and the like.

The driving unit 150 provides control to selectively jet a metallic material 70 to a board 60 through the plurality of nozzles 50a to 50n according to the pulse control signal output from the controlling unit 130, and provides control to sinter the metallic material 70 by using power for driving the plurality of nozzles 50a to 50n to form a circuit pattern 80.

In detail, the driving unit 150 includes a driving controller 152 and an extra power controller 154. The driving controller 152 is responsible for an operation of selectively jetting the metallic material 70 to the board 60 through the plurality of nozzles 50a to 50n. Namely, the driving controller 152 generates a plurality of driving signals corresponding to the plurality of nozzles 50a to 50n according to the pulse control signal output from the controlling unit 130.

Here, the metallic material 60 may be conductive ink containing metal particles such as silver (Ag), copper (Cu), gold (Au), aluminum (Al), iron (Fe), titanium (Ti), or molybdenum (Mo), or the like.

The extra power controller 154 controls extra power, which remains after driving the plurality of nozzles 50a to 50n, to be applied to the metallic material 70, whereby the metallic material 70 is sintered by resistant heat generated by the extra power to form the circuit pattern 80.

Here, the extra power remaining after driving the plurality of nozzles 50a to 50n refers to remaining power excluding driving power used to drive the nozzles from power applied to drive all of the plurality of nozzles 50a to 50n. Here, only some of the nozzles may be used to jet the metallic material 70 to form the circuit pattern 80, so, in this case, the remaining power excluding the driving power used for driving some of the nozzles from the power applied from the power source unit 110 may be a loss. Thus, in order to avoid this, the extra power is re-used to form the circuit pattern 80, thus maximizing energy efficiency.

Meanwhile, resistant heat refers to heat generated when a current flows through a conducting wire having high resistance, namely, heat generated as free electrons collides with other atoms in the conducting wire. As the resistant heat is increased, a loss of electric energy is increased, and when a current flows through a conducting wire having high resistance, heat is generated. The reason is because, free electrons in the conducting wire actively move to greatly collide with atoms, and then, kinetic energy of the atoms is changed into thermal energy due to the collision. Thus, the quantity of heat generated by resistance is called resistant heat.

In this manner, the plurality of nozzles 50a to 50n of the printer head 50 selectively jet conductive ink to directly print the conductive ink on the board 60 and power for driving the plurality of nozzles 50a to 50n, namely, extra power remaining after driving the plurality of nozzles, is applied to both ends of an electrode of the conductive ink to generate resistant heat, and the conductive ink is sintered by using the generated resistant heat, thereby easily forming the circuit pattern 80.

A process of forming a circuit pattern on a PCB according to an exemplary embodiment of the present invention will be described.

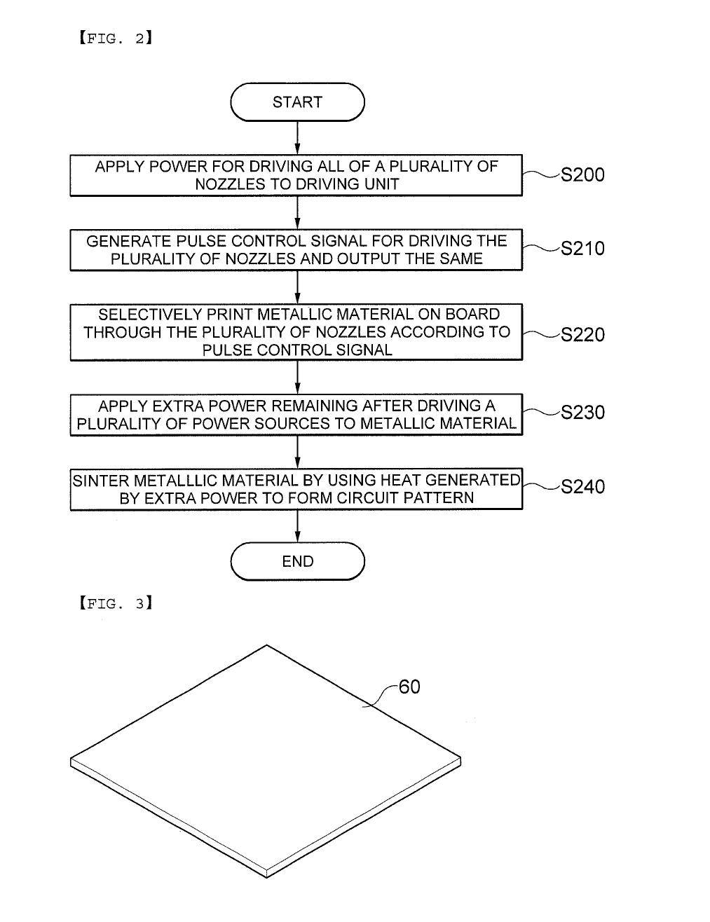

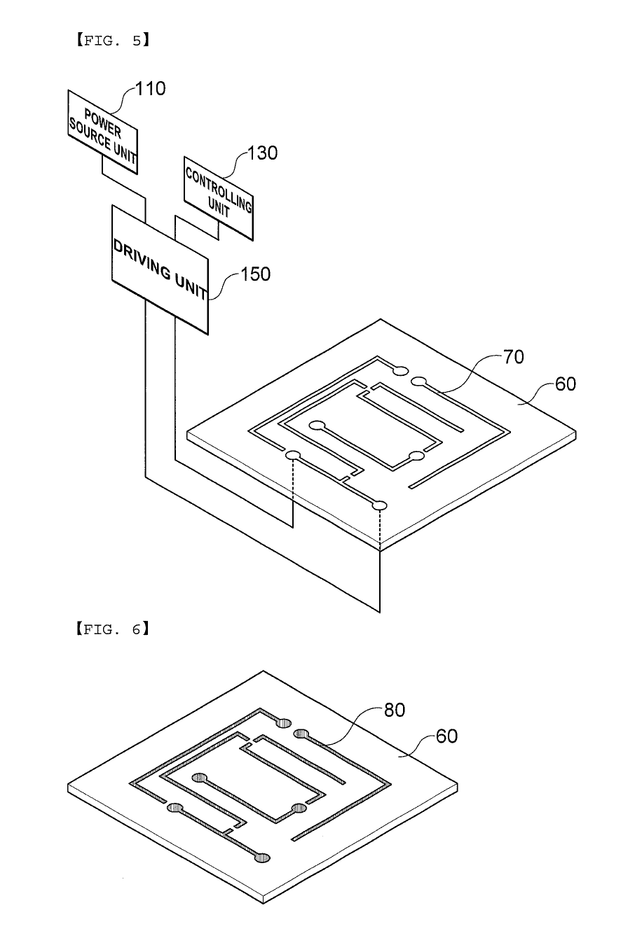

FIG. 2 is a flow chart illustrating a process of forming a circuit pattern on a PCB according to an exemplary embodiment of the present invention, and FIGS. 3 through 6 are views showing a process of forming a circuit pattern on a PCB according to an exemplary embodiment of the present invention.

As shown in FIG. 2, the power source unit 110 generates power for driving all of the plurality of nozzles 50a to 50n and applies the generated power to the driving unit 150 (S200).

Next, a pulse control signal for driving the plurality of nozzles is generated and output (S210). In detail, when an external signal (e.g., a trigger signal) for driving the printer head 50 is applied from the outside, the controlling unit 130 generates a pulse control signal for driving the plurality of nozzles and outputs the generated pulse control signal. The pulse control signal, which is a pulse width modulation (PWM) signal available for adjustment of a duty ratio, may include frequency information, a rising/falling time, information regarding selectively driven nozzles, and the like.

And then, the board 60 as shown in FIG. 3 is prepared. In this case, the board 60 may be made of an organic material such as polyimide, FR4, BT, or the like, and may also be made by using various other materials, without being limited thereto.

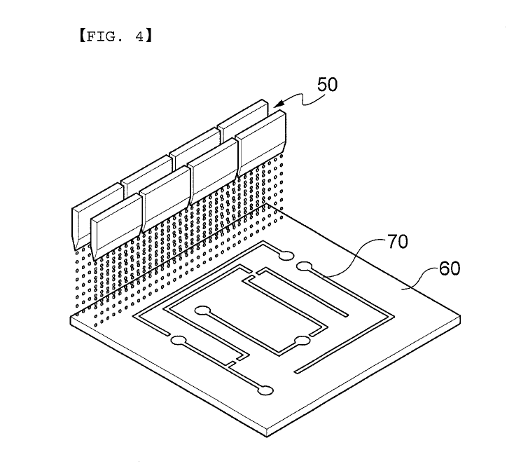

As shown in FIGS. 2 and 4, the metallic material 70 is selectively jetted to the board 60 through the plurality of nozzles 50a to 50n according to the pulse control signal to perform printing (S220).

Thereafter, the metallic material 70 is controlled to be sintered by extra power from the power for driving the plurality of nozzles 50a to 50n to form the circuit pattern 80. In detail, extra power remaining after driving the plurality of nozzles 50a to 50n is applied to the metallic material 70 (S230), and the metallic material 70 is sintered by resistant heat generated by the extra power to form the circuit pattern 80 (S240).

Here, the extra power remaining after driving the plurality of nozzles 50a to 50n refers to remaining power excluding driving power used to drive the nozzles from power applied to drive all of the plurality of nozzles 50a to 50n. Here, only some of the nozzles may be used to jet the metallic material 70 to form the circuit pattern 80, so, in this case, the remaining power excluding the driving power used for driving some of the nozzles from the power applied from the power source unit 110 may be a loss. Thus in order to avoid this, the extra power is re-used to form the circuit pattern 80, thus maximizing energy efficiency.

Meanwhile, resistant heat refers to heat generated when a current flows through a conducting wire having high resistance, namely, heat generated as free electrons collide with other atoms in the conducting wire. As the resistant heat is increased, a loss of electric energy is increased, and when a current flows through a conducting wire having high resistance, heat is generated. The reason is because, free electrons in the conducting wire actively move to greatly collide with atoms, and then, kinetic energy of the atoms is changed into thermal energy due to the collision. Thus, the quantity of heat generated by resistance is called resistant heat.

In this manner, the plurality of nozzles 50a to 50n of the printer head 50 selectively jet conductive ink to directly print the conductive ink on the board 60 and power for driving the plurality of nozzles 50a to 50n, namely, extra power remaining after driving the plurality of nozzles, is applied to both ends of an electrode of the conductive ink. Then, resistant heat is generated to make a solvent organic component included in the metallic material volatile, coupling metal particles.

The sintering-completed metallic material may be formed as the circuit pattern 80 of FIG. 6 as a metal wire assuming metallicity.

Also, since power is locally applied only to the metallic material 70 to form the circuit pattern 80, rather than directly applying heat to the board 60, the board 60 can be prevented from being deformed or degenerated (or denatured).

In addition, since the circuit pattern 80 is directly printed on the board, without performing the exposing, developing and delaminating processes as in the related art, the fabrication process can be simplified to reduce fabrication costs and environmental pollution can be prevented.

According to the exemplary embodiments of the present invention, in an apparatus for forming a circuit pattern on a printed circuit board (PCB) and a method for forming a circuit pattern using the same, after a metallic material is directly printed on the board, power is applied to the metallic material, and the metallic material is sintered by using resistant heat generated accordingly, thus easily forming a circuit pattern.

Also, since a circuit pattern is formed by using a method of locally applying power only to the metallic material, rather than using a method of directly applying heat to the board, the board can be prevented from being deformed or denatured.

Also, since the method of directly printing a circuit pattern on the board, rather than a method of using exposing, developing, and delaminating processes, is used, the fabrication process is simplified to reduce fabrication cost and prevent environmental pollution.

In addition, since a metallic material is printed on the board through a plurality of nozzles and extra power remaining after driving the plurality of nozzles is applied to the metallic material, power, which may be otherwise lost, can be re-used to increase energy efficiency.

Accordingly, reliability of the product including the PCB overall can be enhanced.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A method for forming a pattern on a printed circuit board (PCB), the method comprising:
printing a metallic material on a board through a plurality of nozzles; and
sintering the metallic material with extra power from power for driving the plurality of nozzles to form a circuit pattern.

2. The method according to claim 1, wherein the forming of the circuit pattern includes:
applying extra power remaining after driving the plurality of nozzles to the metallic material; and
sintering the metallic material by using heat generated by the extra power to form a circuit pattern.

3. The method according to claim 2, wherein the extra power remaining after driving the plurality of nozzles is remaining power excluding driving power used to drive the nozzles from power applied to drive all of the plurality of nozzles.

4. The method according to claim 1, wherein the metallic material is conductive ink containing metal particles.

5. The method according to claim 4, wherein, in the printing of the metallic material on the board, the metallic material is printed by selectively jetting the conductive ink from the plurality of nozzles.

6. The method according to claim 1, further comprising:
generating a pulse control signal for driving the plurality of nozzles and outputting the generated pulse control signal, before the printing of the metallic material on the board.

7. The method according to claim 6, further comprising:
generating a plurality of driving signals corresponding to the plurality of nozzles according to the pulse control signal.

8. The method according to claim 1, further comprising:
applying power for driving all of the plurality of nozzles, before the printing of the metallic material on the board.

9. The method according to claim 2, wherein, in the applying of the extra power from the power for driving the plurality of nozzles to the metallic material, the extra power is applied to both ends of an electrode of the metallic material to generate resistant heat.

10. The method according to claim 1, wherein the board is made of an organic material.

11. An apparatus for forming a pattern on a printed circuit board (PCB), the apparatus comprising:
a controlling unit generating a pulse control signal for driving a plurality of nozzles and outputting the generated pulse control signal; and
a driving unit providing control to selectively jet a metallic material to a board through the plurality of nozzles according to the pulse control signal and providing control to sinter the metallic material by extra power from the power for driving the plurality of nozzles to form a circuit pattern.

12. The apparatus according to claim 11, wherein the driving unit provides control to apply extra power remaining after driving the plurality of nozzles to the metallic material.

13. The apparatus according to claim 12, wherein the metallic material is sintered by resistant heat generated by the extra power to form the circuit pattern.

14. The apparatus according to claim 12, wherein the driving unit includes a driving controller generating a plurality of driving signals corresponding to the plurality of nozzles according to the pulse control signal.

15. The apparatus according to claim 12, wherein the driving unit includes an extra power controller providing control to apply extra power remaining after driving the plurality of nozzles to the metallic material.

16. The apparatus according to claim 15, further comprising:
a power source unit applying power for driving all of the plurality of nozzles to the driving unit.

17. The apparatus according to claim 16, wherein the extra power of the power for driving the plurality of nozzles is remaining power excluding driving power used to drive the nozzles from power applied to drive all of the plurality of nozzles.
